(19) United States
(12) Patent Application Publication
(10) Pub. No.: US 2025/0366154 A1
(43) Pub. Date: Nov. 27, 2025

(54) PROTECTION LAYER FOR REDUCING STI LOSS AND THE METHODS OF FORMING THE SAME

(71) Applicant: Taiwan Semiconductor Manufacturing Co., Ltd., Hsinchu (TW)

(72) Inventors: Chang-Miao Liu, Hsinchu (TW); Huiling Shang, Hsinchu (TW); Ko-Cheng Liu, Hsinchu (TW)

(21) Appl. No.: 18/781,173

(22) Filed: Jul. 23, 2024

Related U.S. Application Data
(60) Provisional application No. 63/651,043, filed on May 23, 2024.

(51) Int. Cl. H01L 21/8234; H01L 27/088; H01L 29/06; H01L 29/423; H01L 29/66; H01L 29/775; H01L 29/786

(52) U.S. Cl. CPC H10D 84/038; H10D 30/014; H10D 64/015; H10D 84/0151; H10D 30/43; H10D 30/6735; H10D 30/6757; H10D 62/121; H10D 64/017; H10D 84/83

(57) ABSTRACT

A method includes forming a shallow trench isolation region aside of a protruding fin. The protruding fin includes a first semiconductor nanostructure and a second semiconductor nanostructure. The method further includes forming a hard mask on the shallow trench isolation region, forming a dummy gate stack over the protruding fin, removing a sacrificial layer in the protruding fin to leave a space between the first semiconductor nanostructure and the second semiconductor nanostructure, forming a disposable interposer in the space, removing the dummy gate stack, removing the disposable interposer using an etching chemical, wherein when the disposable interposer is removed, the hard mask is exposed to the etching chemical, and forming a gate stack, wherein a portion of the gate stack is filled in the space.

### PRIORITY CLAIM AND CROSS-REFERENCE

This application claims the benefit of the following provisionally filed U.S. Patent application: Application No. 63/651,043, filed on May 23, 2024, and entitled “SEMICONDUCTOR STRUCTURE,” which application is hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 18A and 18B illustrate the views of intermediate stages in the formation of transistors in accordance with some embodiments.

FIG. 19 illustrates a process flow for forming transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate-All-Around (GAA) transistor and the method of forming the same are provided. In accordance with some embodiments of the present disclosure, the formation of the GAA transistor adopts Disposable Oxide Interposing (DOI) processes, which includes forming sacrificial layers comprising oxides. Since the sacrificial layers do not have enough etching selectivity relative to Shallow Trench Isolation (STI) regions, the STI regions may be undesirable recessed, causing the undesirable increase in effective capacitance Ceff between conductive features, and the undesirable increase of out fringe capacitance. A protection layer (also referred to as a hard mask) is thus formed on the STI regions to prevent the STI regions from being recessed during the removal of the sacrificial layers.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

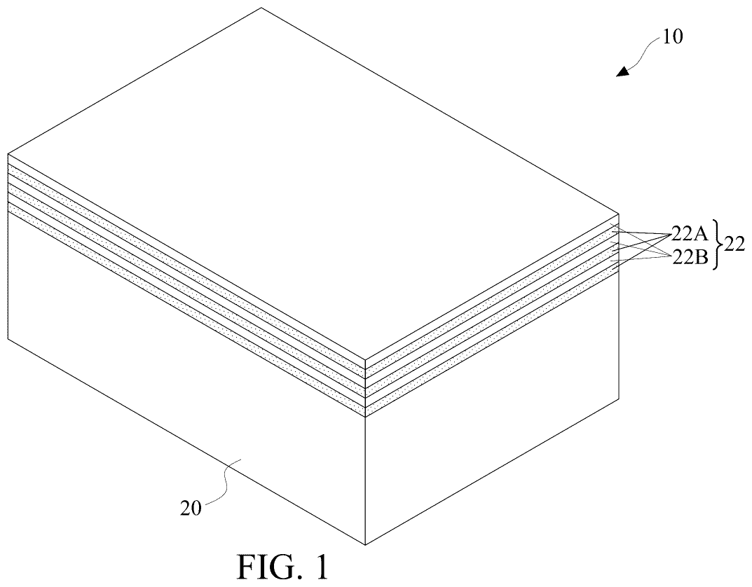

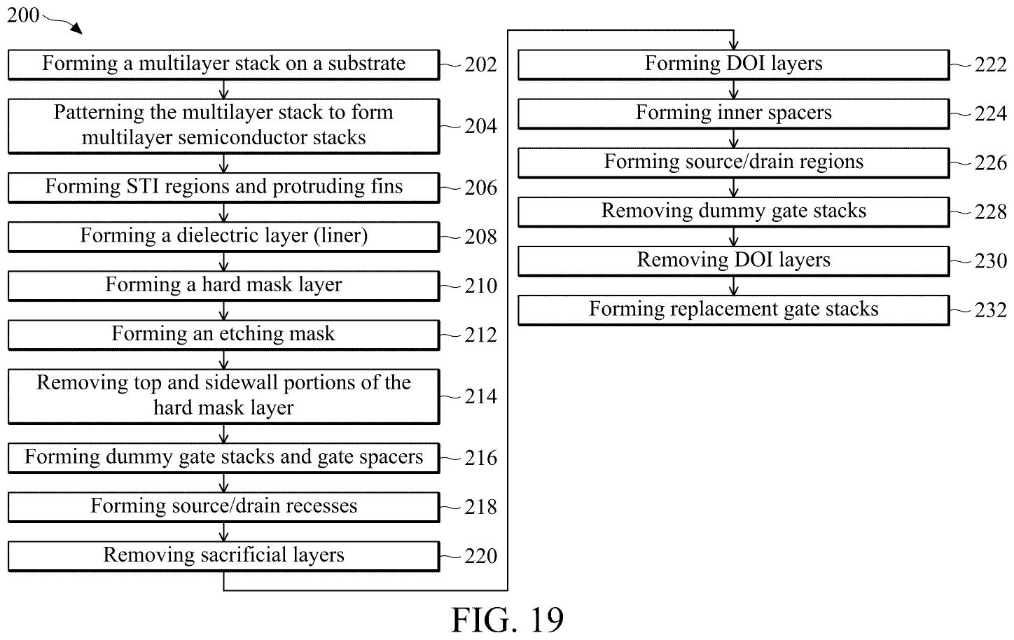

FIG. 1 through FIGS. 18A and 18B illustrate the cross-sectional views of intermediate stages in the formation of an GAA transistor in accordance with some embodiments of the present disclosure. The corresponding processes are also reflected schematically in the process flow 200 shown in FIG. 19.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 19. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask(s) (not shown) formed over multilayer stack 22. These layers are patterned, and are used for the subsequent patterning of multilayer stack 22.

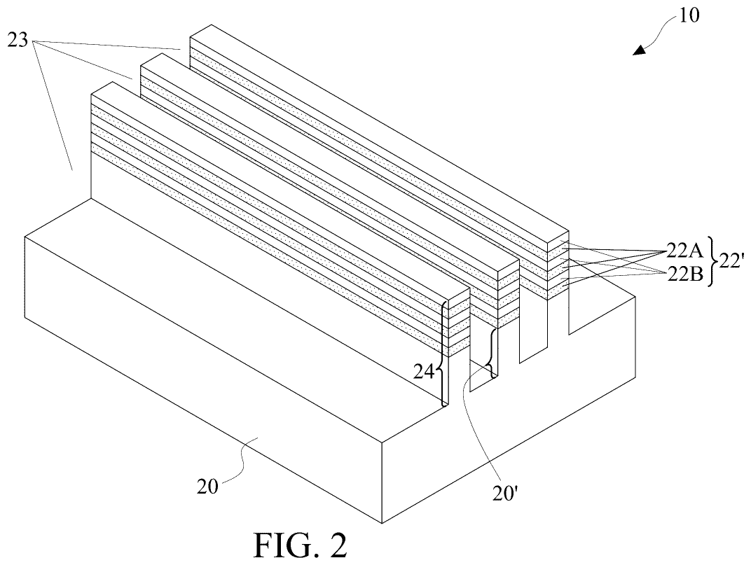

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 19. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

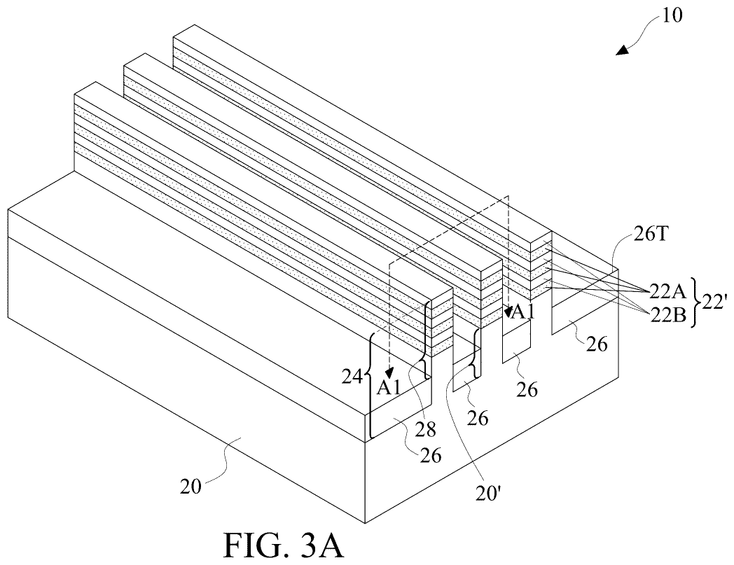

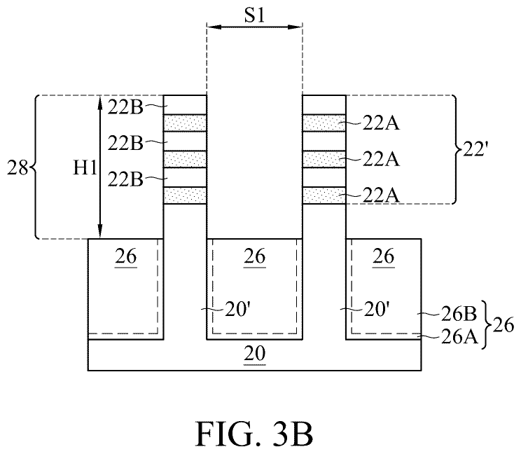

FIG. 3A illustrates the formation of isolation regions 26, which are also referred to as Shallow Trench Isolation (STI) regions throughout the description. The respective process is illustrated as process 206 in the process flow 200 shown in FIG. 19. STI regions 26 may include a dielectric liner (refer to FIG. 3B), which may be a thermal oxide formed through the thermal oxidation of a surface layer of substrate 20. The dielectric liner may also be a deposited silicon oxide layer formed using, for example, ALD, High-Density Plasma Chemical Vapor Deposition (HDPCVD), CVD, or the like. STI regions 26 may also include a dielectric material over the dielectric liner, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

FIG. 3B illustrates a cross-section A1-A1 in FIG. 3A. As shown in FIG. 3B, STI regions 26 may include dielectric liner 26A, and dielectric region 26B on dielectric liner 26A. Dielectric liner 26A and dielectric region 26B may be formed of different dielectric materials or a same dielectric material. For example, dielectric liner 26A may be formed of silicon nitride or silicon oxide, while dielectric region 26B may be formed of silicon oxide or silicon nitride. Dielectric liner 26A and dielectric region 26B may also be formed of a same dielectric material such as silicon oxide, but have different properties. For example, dielectric region 26B may have a lower density and a higher etching rate than dielectric liner 26A. In accordance with alternative embodiments, the entireties of STI regions 26 are formed of a homogeneous material such as silicon oxide. In subsequent figures, dielectric liner 26A and dielectric region 26B are not shown separately.

In accordance with some embodiments, the spacing S1 between neighboring protruding fins 28 may be in the range between about 20 nm and about 200 nm. The height H1 of the protruding fins 28 may be in the range between about 50 nm and about 70 nm.

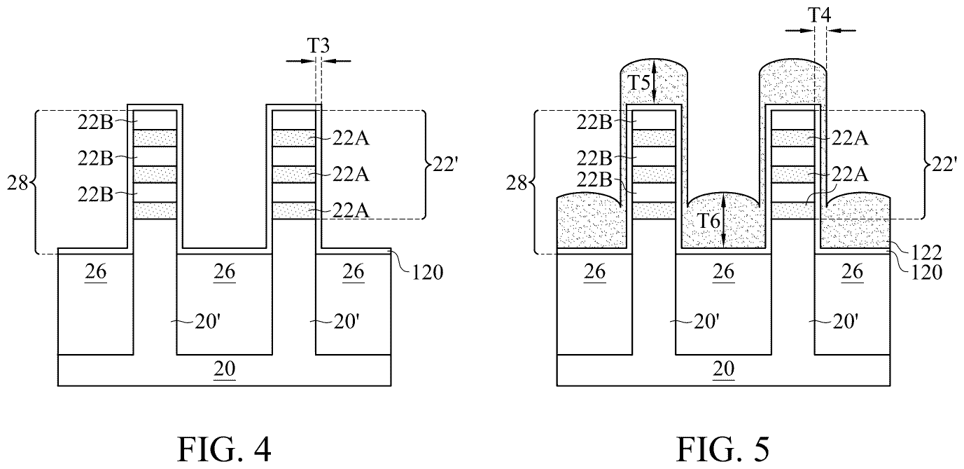

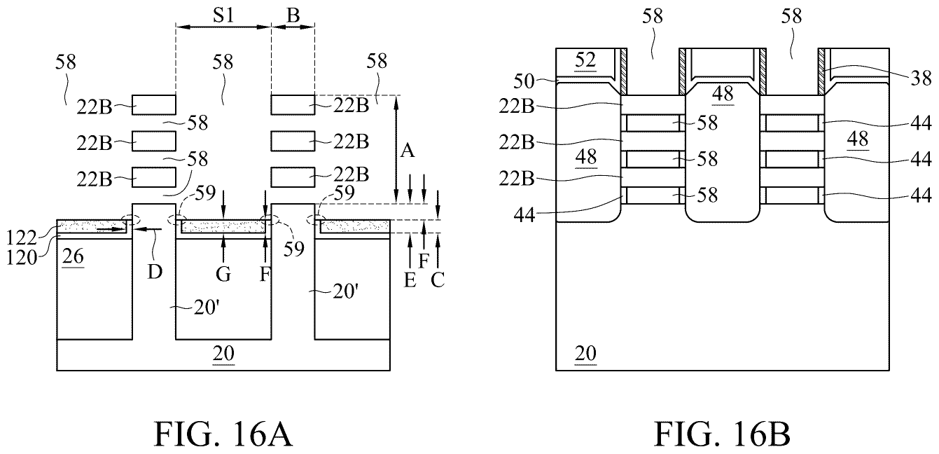

Referring to FIG. 4, dielectric layer 120 is formed. The respective process is illustrated as process 208 in the process flow 200 shown in FIG. 19. In accordance with some embodiments, dielectric layer 120 comprises silicon oxide. The formation may include a deposition process, which may be a conformal deposition process such as ALD, CVD, or the like. The thickness T3 of dielectric layer 120 cannot be too small. Otherwise, it cannot effectively protect protruding fins 28 in subsequent etching processes. The thickness of T3 of dielectric layer 120 also cannot be too great. Otherwise, edge sagging may occur, as will be discussed referring to FIG. 16A. In accordance with some embodiments, thickness of T3 of dielectric layer 120 is in the range between about 1 nm and about 8 nm, and may be in the range between about 1 nm and about 4 nm.

FIG. 5 illustrates the deposition of hard mask layer 122 (also referred to as protection layer 122). The respective process is illustrated as process 210 in the process flow 200 shown in FIG. 19. In accordance with some embodiments, hard mask layer 122 is formed as a non-conformal layer, which has sidewall portions having thickness T4, top portions having thickness T5, and bottom portions having thickness T6. The thicknesses T5 and T6 are greater than thickness T4. For example, the ratios T5/T4 and T6/T4 may be in the range between about 3 and about 20.

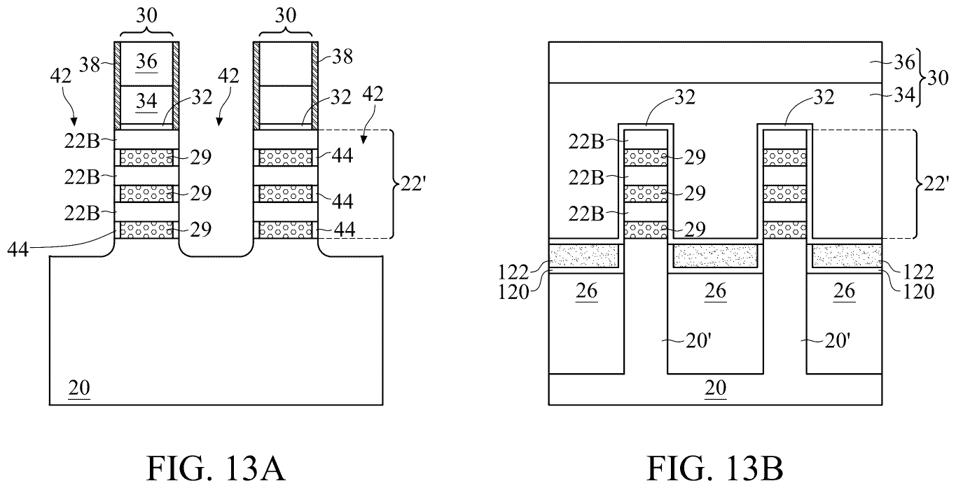

Hard mask layer 122 is formed of a dielectric material that is different from (and having high etching selectivity relative to) the dielectric material of the underlying STI regions 26. The material of hard mask layer 122 may also be different from (and having high etching selectivity relative to) the material of the subsequently formed disposable oxide interposers 29 (FIGS. 13A and 13B). The etching selectivity may be higher than about 10, and may be in the range between about 10 and 100, for example.

In accordance with some embodiments, hard mask layer 122 may be formed of or comprises a silicon-and-nitrogen dielectric material and/or a silicon-and-carbon containing dielectric material such as SiN, SiCN, SION, SiCON, SiC, SiOC, or the like. Hard mask layer 122 may also comprise a high-k dielectric material such as Al₂O₃ (ALD), HfO₂, HfSiO, ZrO₂, La₂O₃, Y₂O₃, or the like, or combinations thereof. Hard mask layer 122 may also comprise an inorganic or an organic low-k material such as Fluorine-doped Silicate Glass (FSG), porous carbon-doped oxide (such as porous SiOC), xerogel, aerogel, amorphous fluorinated carbon, parylene, benzocyclobutene (BCB), polyimide, or the like.

In accordance with some embodiments, the formation of the non-conformal hard mask layer 122 may include a plurality of cycles. Each of the cycles may include depositing a silicon layer, followed by a nitridation process to convert the silicon layer into a silicon nitride layer. The deposition process may also include ALD, CVD, PVD, RPCVD, PECVD, HDPCVD, FCVD, HARP, LPCVD, ALCVD, APCVD, SACVD, MOCVD, or the like, or combinations thereof. In accordance with some embodiments, the deposition of the silicon layer is performed using plasma deposition with a bias power applied. Accordingly, the horizontal portions of the silicon layer on top of the protruding fins 28 and at the bottoms of the spaces (between the protruding fins 28) have more dangling bonds due to the plasma, while the vertical portions of the silicon layer on the sidewalls of the protruding fins 28 have fewer dangling bonds.

In the nitridation process, the horizontal portions of the silicon layer have a higher conversion rate (converted to silicon nitride) due to the more dangling bonds, and the sidewall portions of the silicon layer have lower conversion rate. The un-converted portions of the silicon layer on the sidewalls may be vacated out of the respective process chamber during the conversion process. Accordingly, the resulting silicon nitride layer is non-conformal. Through the plurality of cycles, the thickness of the silicon nitride layer is increased in each cycle and to the desirable thickness.

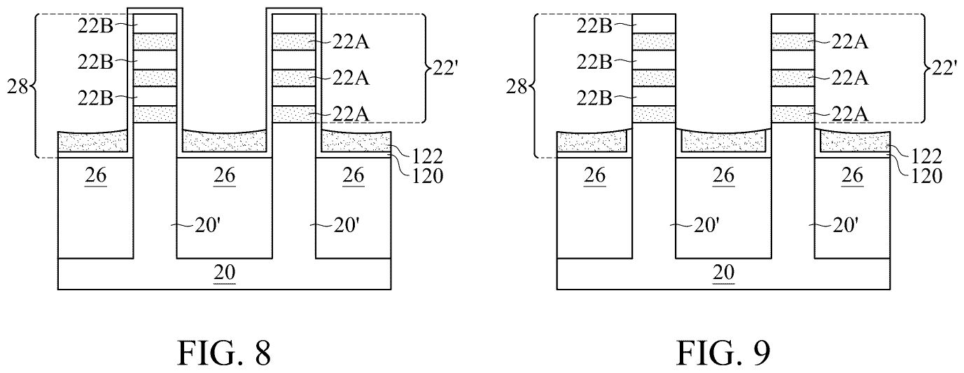

In accordance with alternative embodiments, the hard mask layer 122 is formed as a conformal layer. In accordance with these embodiments, silicon nitride may be deposited through plasma deposition with bias power applied (for example, through ALD, CVD, or the like). The top portions and bottom portions of the hard mask layer 122, which may comprise silicon nitride, may be denser and harder than the sidewall portions. As a result, in the subsequent etching processes as shown in in FIGS. 7 and 8, the sidewall portions have a higher etching rate, and are fully removed when the bottom portions still have some portions left. Accordingly, the bottom portions may have an adequate thickness for it to act as a protection layer in subsequent sheet formation process as shown in FIG. 16A.

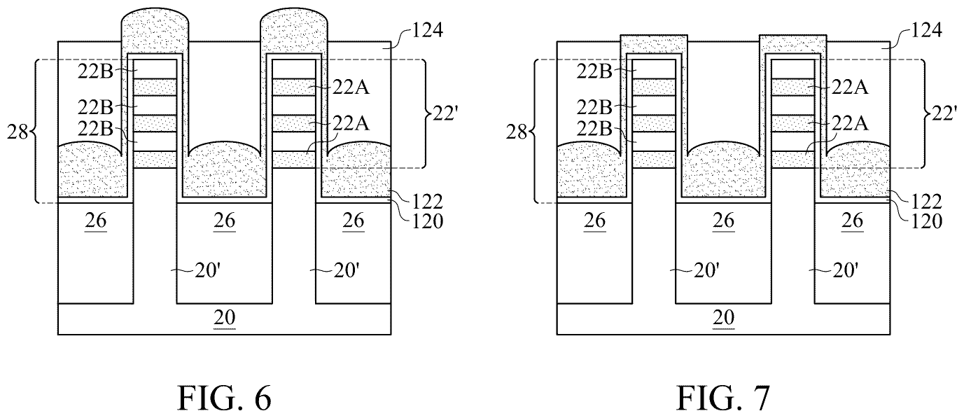

FIG. 6 illustrates the formation of sacrificial layer 124, which is used as an etching mask. The respective process is illustrated as process 212 in the process flow 200 shown in FIG. 19. In accordance with some embodiments, sacrificial layer 124 includes a material that may be used as a Bottom Anti-Reflective Coating (BARC), and may include a cross-linked photoresist, SiOC, or the like. The formation of sacrificial layer 124 may include a deposition (or dispensing) process, followed by a planarization process, and then an etch-back process. The top portions of the hard mask layer 122 are thus exposed.

FIG. 7 illustrates an etching process to remove some top portion of the hard mask layer 122. The etching chemical is selected to have a low etching rate on dielectric layer 120. The etching may be performed through a dry etching process, a wet etching process, or the like. In accordance with some embodiments, the etching gas may include a fluorine-containing gas such as CF₄, NF₃, SF₆, CHF₃, CIF₃, or the like, or combinations thereof. Other gases such as O₂, N₂, H₂, Ar, NO, and the like, may also be added. In accordance with alternative embodiments, a wet etching process may be adopted, for example, using H₃PO₄. After the etching process, the top portion of the hard mask layer 122 may be fully removed to expose dielectric layer 120, or may have a thin portion remaining.

The sacrificial layer 124 is then removed, followed by an etching process to remove the top portions (when remaining) and sidewalls portions of hard mask layer 122. The respective process is illustrated as process 214 in the process flow 200 shown in FIG. 19. The resulting structure is shown in FIG. 8. The remaining portions of hard mask layer 122 are also referred to as hard masks 122. The etching process may be isotropic, and may be performed through a dry etching process or a wet etching process, for example, using the aforementioned chemical that are used for removing the top portions of the hard mask layer 122. Dielectric layer 120 is used as an etch stop layer.

In the etching of the sacrificial layer 124, in accordance with some embodiments in which the sidewall portions (vertical portions) of the hard mask layer 122 are thinner than the bottom portions, the etching process is controlled, so that the top portions and the sidewall portions are fully removed, while the bottom portions have at least some portions remaining. In the embodiments in which the sidewall portions have the same thickness as, but is less dense than the bottom portions, the sidewall portions are etched faster than the bottom portions. When the sidewall portions are fully removed, the bottom portions have at least some portions remaining.

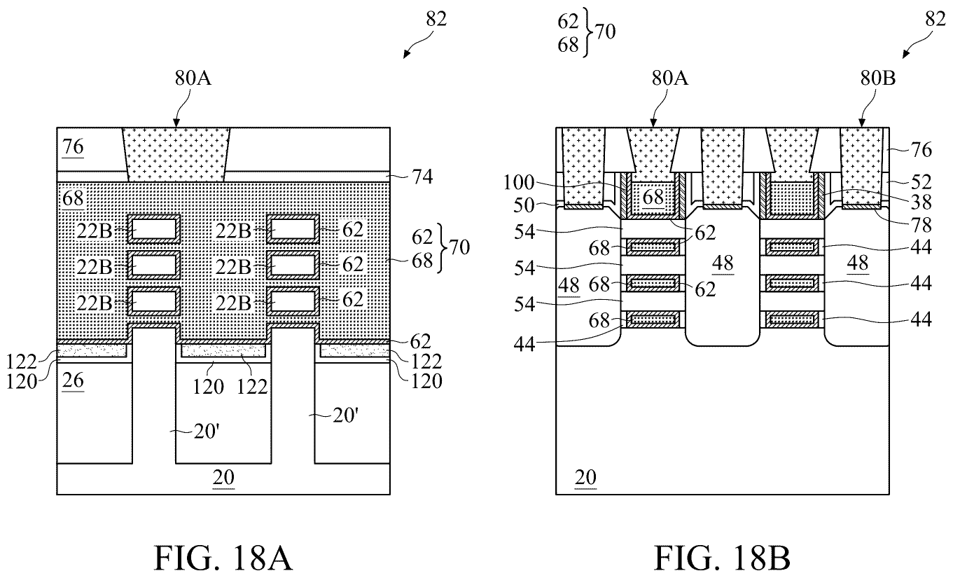

In accordance with some embodiments, as shown in FIG. 8, due to the etching, the hard masks 122 may have curved top surfaces, with middle portions of the curved top surface in the middle between neighboring semiconductor strips 20′ being at lower levels than the portions closer to semiconductor strips 20′. Although the top surfaces of hard masks 122 are not shown as being curved in subsequent figures, the top surfaces of hard masks 122 may also be curved, for example, in the final structure shown in FIGS. 18A and 18B.

In accordance with some embodiments, when the etching is stopped, the remaining hard masks 122 are not too thick and not too thin. The hard masks 122 that are too thin posts a challenge to the process control, and non-uniformity throughout the wafer may cause the hard masks 122 in some portion of the wafer to be etched fully or too thin, and not able to protect the underlying STI regions in the subsequent sheet formation process. The hard masks 122 that are too thick may result in the capacitance between the subsequently formed gate electrode and semiconductor strip 20′ (also referred to as a semiconductor protrusion) to be too high due to the high dielectric constant of the hard masks 122. In accordance with some embodiments, the thickness of the remaining hard masks 122 is in the range between about 0.5 nm and about 10 nm.

The dielectric layer 120 is then etched, exposing the protruding fins 28. The resulting structure is shown in FIG. 9. Some portions of the dielectric layer 120 on the sidewalls of hard masks 122 and below hard masks 122 are left to act as dielectric liners, and are also referred to as dielectric liners 120. Throughout the description, hard masks 122 and the respective dielectric liners 120 are collectively referred to as hard masks 122/120, or composite hard masks 122/120.

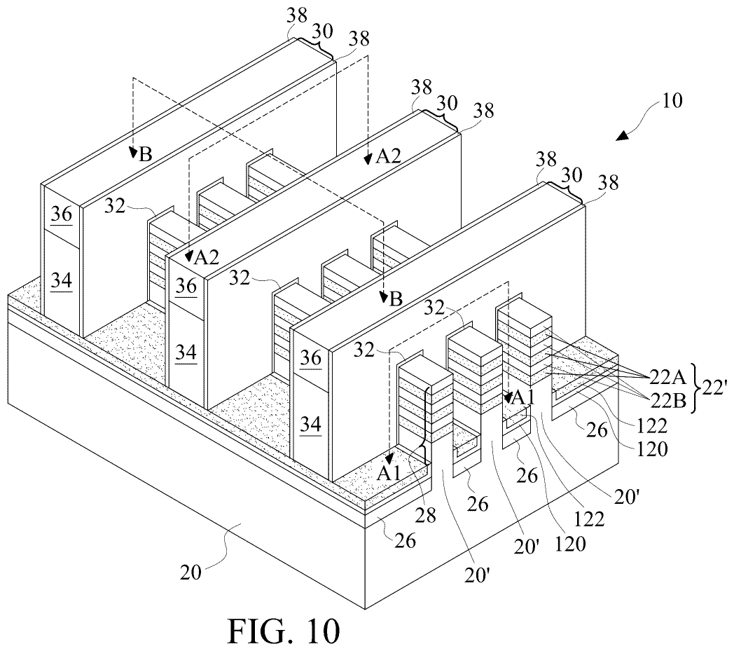

Referring to FIG. 10, which shows a perspective view, dummy gate stacks 30 and gate spacers 38 are formed on the top surfaces and the sidewalls of (protruding) fins 28. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask 36 over dummy gate electrode 34. Hard masks 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard masks, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

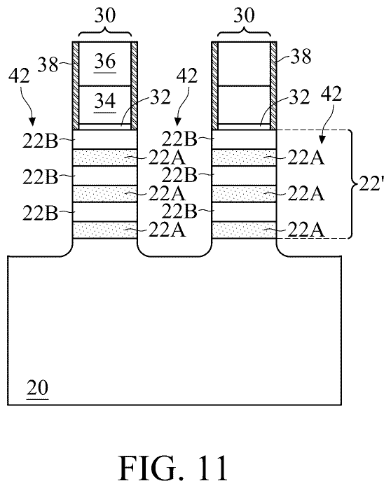

FIG. 11 illustrates the source/drain recessing process. The respective process is illustrated as process 218 in the process flow 200 shown in FIG. 19. The protruding fins 28 that are not directly underlying dummy gate stacks 30 and gate spacers 38 are etched in an anisotropic etching process. Source/drain recesses 42 are thus formed, as shown in FIG. 11. FIG. 11 illustrates the cross-section B-B as shown in FIG. 10.

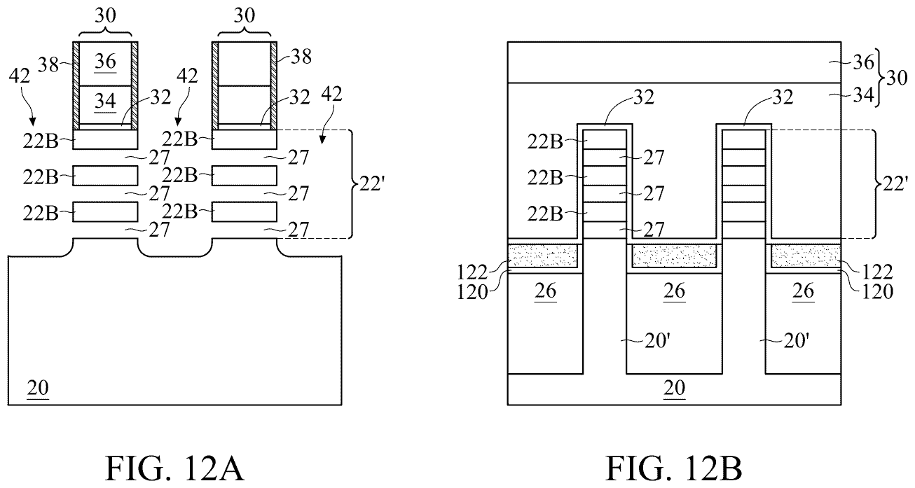

FIGS. 12A, 12B, 13A, and 13B illustrate the replacement of sacrificial layers 22A with disposable interposers 29. Referring to FIGS. 12A and 12B, which illustrate the cross-sections B-B and A2-A2, respectively in FIG. 10, the sacrificial layers 22A are first removed, forming openings 27 between nanostructures 22B. The respective process is illustrated as process 220 in the process flow 200 shown in FIG. 19.

Referring to FIGS. 13A and 13B, disposable interposers 29 are formed between nanostructures 22B. The respective process is illustrated as process 222 in the process flow 200 shown in FIG. 19. In accordance with some embodiments, disposable interposers 29 comprise an oxide such as silicon oxide, and thus may also be referred to as Disposable Oxide Interposers (DOIs) 29. In accordance with other embodiments, other types of oxides may be adopted.

The formation of disposable interposers 29 may include depositing a dielectric layer using a conformal deposition process, so that the dielectric layer includes some portions filling openings 27, and some other portions outside of openings 27. A trimming process, which may be an isotropic etching process, is then performed to etch and remove the portions of the dielectric layer outside of openings 27. The remaining portions of the dielectric layer are thus the disposable interposers 29.

Disposable interposers 29 are then laterally recessed to form inner spacers 44 (FIG. 13A). The lateral recessing of disposable interposers 29 may be achieved through a wet etching process or a dry etching process. The wet etching process may be performed using a dip process, a spray process, a spin-on process, or the like. Nanostructures 22B are not etched.

Inner spacers 44 are then formed. The respective process is illustrated as process 224 in the process flow 200 shown in FIG. 19. In accordance with some embodiments, the formation of inner spacers 44 includes depositing a conformal dielectric layer, which extends into the lateral recesses. Next, an etching process (also referred to as a spacer trimming process) is performed to trim the portions of the dielectric layer outside of the lateral recesses, leaving the portions of the dielectric layer in the lateral recesses. The remaining portions of the dielectric layer are referred to as inner spacers 44.

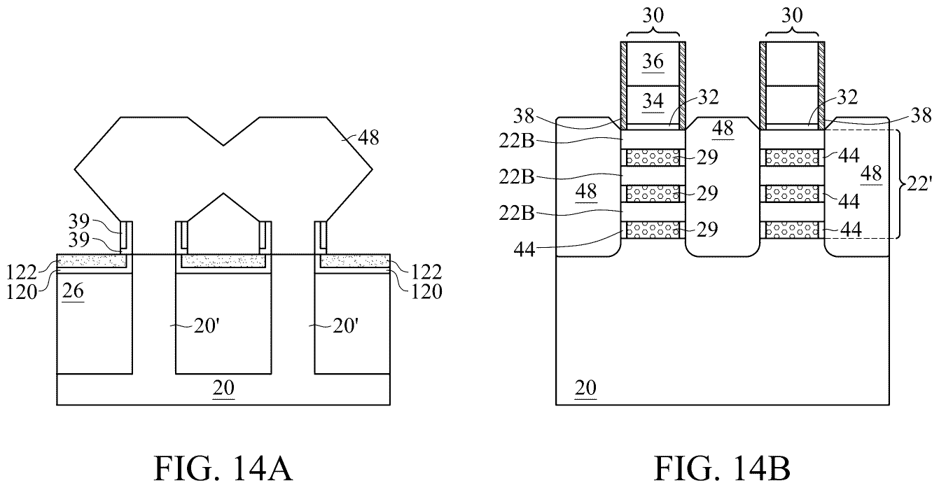

Referring to FIGS. 14A and 14B, which illustrate the same cross-section as the cross-sections A1-A1 and B-B, respectively in FIG. 10, epitaxial source/drain regions 48 are formed in recesses 42 through selective epitaxy. The respective process is illustrated as process 226 in the process flow 200 shown in FIG. 19. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown.

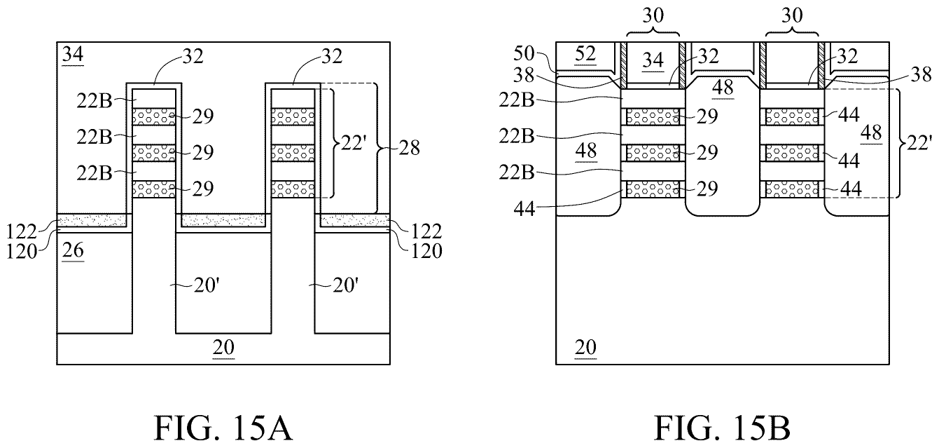

FIGS. 15A and 15B illustrate the cross-sectional views of the structure after the formation of Contact Etch Stop Layer (CESL) 50 and Inter-Layer Dielectric (ILD) 52. FIGS. 15A and 15B illustrate the cross-sections A2-A2 and B-B, respectively, in FIG. 10. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIGS. 15A and 15B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

Next, dummy gate electrodes 34 and dummy gate dielectrics 32 (and hard masks 36, if remaining) are removed in one or more etching processes, so that recesses 58 are formed, as shown in FIGS. 16A and 16B. The respective process is illustrated as process 228 in the process flow 200 shown in FIG. 19. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Disposable interposers 29 are then removed to extend recesses 58 between nanostructures 22B. The respective process is illustrated as process 230 in the process flow 200 shown in FIG. 19. Disposable interposers 29 may be removed by performing an isotropic etching process such as a wet etching process using etchants that are selective to the materials of disposable interposers 29, while nanostructures 22B and substrate 20 remain relatively un-etched as compared to disposable interposers 29. In accordance with some embodiments in which disposable interposers 29 include, for example, silicon oxide, the mixture of NF₃ and NH₃, the mixture of HF and NH₃, and HF may be used to remove disposable interposers 29.

In the etching of disposable interposers 29, the STI regions 26 are protected from the etching chemical by hard masks 122 due to the high etching selectivity, which is the ratio of the etching rate of disposable interposers 29 to the etching rate of the hard masks 122. It is appreciated that in the removal of the disposable interposers 29, the remaining portions of dielectric layer 120 may be recessed. For example, the portions of dielectric layer 120 in dashed circles 59 in FIG. 16A may be removed, and the top surfaces of the sidewall portions of the dielectric layer 120 are recessed to be lower than the top surfaces of hard masks 122. Due to the selected small thickness of dielectric layer 120, however, the recessing of dielectric layer 120 is controlled, and the bottom portions of dielectric layer 120 may remain. The top surfaces of hard masks 122 also may have dishing, with the middle portion of the top surfaces being lower than the respective opposite portions.

Some example dimensions are discussed referring to FIG. 16A. The nanostructures 22B may have height A, which may be in the range between about 50 nm and about 70 nm. height A is calculated from a top surface of nanostructure to a top surface fin/protrusion 20′, and is also referred to as a thickness. The nanostructures 22B may have heights in the range between about 6 nm and about 10 nm. The spacings between nanostructures 22B may be in the range between about 8 nm and about 10 nm. The width B of nanostructure 22B may be in the range between about 20 nm and about 30 nm, with the spacing S1 in the range between about 20 nm and about 200 nm. The thickness C of the hard masks 122 may be in the range between about 0.5 nm and about 20 nm, and may be in the range between about 0.5 nm and about 10 nm, or in the range between about 10 nm and about 20 nm. The thickness D of dielectric layer 120 may be in the range between about 1 nm and about 8 nm, and may be in the range between about 1 nm and about 4 nm, or in the range between about 4 nm and about 8 nm.

The distance E from the top of semiconductor strip 20′ to the bottom of hard masks 122 may be in the range between about 5 nm and about 20 nm. The distance F from the top of semiconductor strip 20′ to the top of hard masks 122 (at the edge of hard mask 122) may be in the range between about 2 nm and about 5 nm. The distance G from the top of semiconductor strip 20′ to the top of hard masks 122 (at the center of hard mask 122) may be in the range between about 2 nm and about 8 nm.

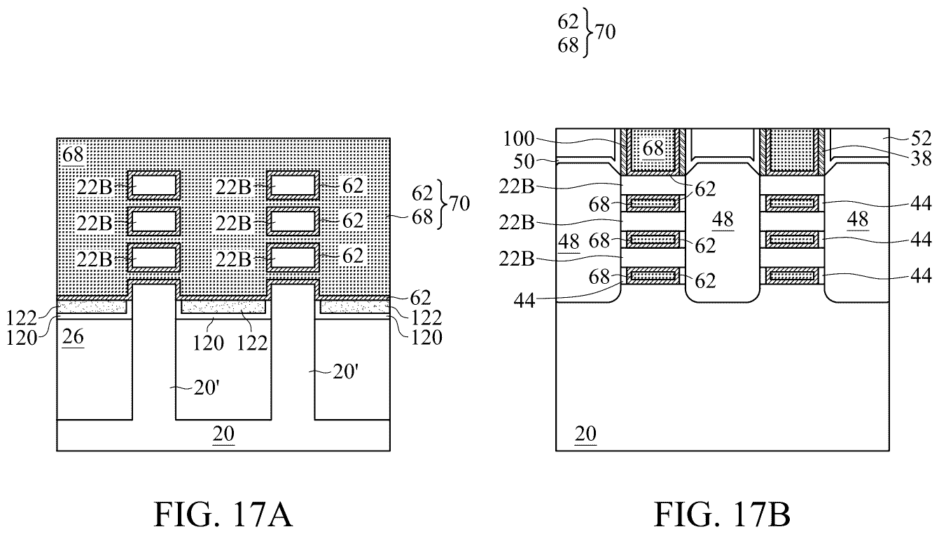

Referring to FIGS. 17A and 17B, gate dielectrics 62 and gate electrodes 68 are formed, hence forming replacement gate stacks 70. The respective process is illustrated as process 232 in the process flow 200 shown in FIG. 19. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiment, the interfacial layer may be formed on both of the nanostructures 22B and semiconductor strips 20′. In accordance with some embodiments, the high-k dielectric layers comprise one or more high-k dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAIC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′.

After the filling of recesses 58, a planarization process such as a CMP process or a mechanical grinding process is performed to remove the excess portions of the gate dielectrics 62 and gate electrodes 68, which excess portions are over the top surface of ILD 52. Gate electrodes 68 and gate dielectrics 62 are collectively referred to as gate stacks 70 of the resulting transistors.

In the processes shown in FIGS. 18A and 18B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 18A and 18B, ILD 76 is deposited over ILD 52 and over gate masks 74. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

ILD 76, ILD 52, CESL 50, and gate masks 74 are then etched to form recesses (occupied by contact plugs 80A and 80B) exposing surfaces of source/drain regions 48 and/or gate stacks 70. Although FIG. 18B illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. Contact plugs 80B are then formed over silicide regions 78. Also, contacts 80A (may also be referred to as gate contact plugs) are also formed in the recesses, and are over and contacting gate electrodes 68. The corresponding structure is also shown in FIG. 18A. Transistor 82 is thus formed.

The embodiments of the present disclosure have some advantageous features. By forming a hard mask on top of the STI regions, in the removal of the disposable interposers, the hard mask protects the STI regions from being recessed. The undesirable increase in the parasitic capacitance between gate electrodes and semiconductor strips is thus reduced.

In accordance with some embodiments of the present disclosure, a method comprises forming a shallow trench isolation region aside of a protruding fin; forming a hard mask on the shallow trench isolation region; forming a dummy gate stack over the protruding fin; removing a sacrificial layer in the protruding fin to leave a space between a first semiconductor nanostructure and a second semiconductor nanostructure, wherein the first semiconductor nanostructure and the second semiconductor nanostructure are comprised in the protruding fin; forming a disposable interposer in the space; removing the dummy gate stack; removing the disposable interposer using an etching chemical, wherein when the disposable interposer is removed, the hard mask is exposed to the etching chemical, and a bottom portion of the hard mask remains after the disposable interposer is removed; and forming a gate stack, wherein a portion of the gate stack is filled in the space.

In an embodiment, the hard mask is deposited to comprise a top portion overlapping the protruding fin and having a first thickness; and a sidewall portion on a sidewall of the protruding fin and having a second thickness smaller than the first thickness. In an embodiment, the method further comprises, before the dummy gate stack is formed, removing the top portion and the sidewall portion, wherein a bottom portion of the hard mask remains. In an embodiment, the forming the hard mask comprises forming a silicon nitride layer. In an embodiment, the forming the silicon nitride layer comprises a plurality of cycles, and each of the plurality of cycles comprises depositing a silicon layer; and performing a nitridation process on the silicon layer.

In an embodiment, the depositing the silicon layer is performed with a bias power applied, and the silicon nitride layer generated by the nitridation process has a sidewall thickness and a bottom thickness greater than the sidewall thickness. In an embodiment, the method further comprises, before the hard mask is formed, depositing a dielectric layer on the protruding fin.

In an embodiment, the dielectric layer comprises a same dielectric material as the shallow trench isolation region. In an embodiment, when the disposable interposer is etched, the shallow trench isolation region is separated from the etching chemical by the bottom portion of the hard mask. In an embodiment, the gate stack contacts the bottom portion of the hard mask.

In accordance with some embodiments of the present disclosure, a structure comprises a semiconductor strip; a first semiconductor nanostructure overlapping, and spaced apart from, the semiconductor strip; a shallow trench isolation region contacting an edge of the semiconductor strip; a gate stack comprising a first portion between the first semiconductor nanostructure and the semiconductor strip; and a hard mask between the shallow trench isolation region and the gate stack. In an embodiment, the hard mask comprises a different dielectric material than the shallow trench isolation region.

In an embodiment, the hard mask comprises silicon nitride, and the shallow trench isolation region comprise silicon oxide. In an embodiment, the structure further comprises a dielectric liner between, and in contact with, the hard mask and the semiconductor strip. In an embodiment, the structure further comprises a second semiconductor nanostructure overlapping, and spaced apart from, the first semiconductor nanostructure, wherein the gate stack further comprises a third portion between the first semiconductor nanostructure and the second semiconductor nanostructure. In an embodiment, a topmost end of the hard mask is lower than a top end of the semiconductor strip.

In accordance with some embodiments of the present disclosure, a structure comprises a semiconductor substrate; a shallow trench isolation region in the semiconductor substrate, wherein a portion of the semiconductor substrate is aside of and contacting the shallow trench isolation region to act as a semiconductor strip; a dielectric liner over and contacting the shallow trench isolation region; a dielectric hard mask over the dielectric liner, wherein a sidewall portion of the dielectric liner comprises opposing sidewalls contacting the dielectric hard mask and the semiconductor strip; and a gate stack over and contacting the dielectric hard mask.

In an embodiment, the dielectric hard mask is formed of a different material than the shallow trench isolation region. In an embodiment, the dielectric hard mask comprises a curved top surface, with a middle portion of the curved top surface being lower than portions of the curved top surface on opposite sides of the middle portion. In an embodiment, the structure further comprising a plurality of semiconductor nanostructures, wherein upper ones of the plurality of semiconductor nanostructures overlap lower ones of the plurality of semiconductor nanostructures, and wherein the gate stack comprises portions between neighboring ones of the plurality of semiconductor nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a shallow trench isolation region aside of a protruding fin, wherein the protruding fin comprises a first semiconductor nanostructure and a second semiconductor nanostructure;
forming a hard mask on the shallow trench isolation region;
forming a dummy gate stack over the protruding fin;
removing a sacrificial layer in the protruding fin to leave a space between the first semiconductor nanostructure and the second semiconductor nanostructure;
forming a disposable interposer in the space;
removing the dummy gate stack;
removing the disposable interposer using an etching chemical, wherein when the disposable interposer is removed, the hard mask is exposed to the etching chemical; and
forming a gate stack, wherein a portion of the gate stack is filled in the space.

2. The method of claim 1, wherein the hard mask is deposited to comprise:
a top portion overlapping the protruding fin and having a first thickness; and
a sidewall portion on a sidewall of the protruding fin and having a second thickness smaller than the first thickness.

3. The method of claim 2 further comprising:
before the dummy gate stack is formed, removing the top portion and the sidewall portion, wherein a bottom portion of the hard mask remains.

4. The method of claim 1, wherein a bottom portion of the hard mask remains after the disposable interposer is removed.

5. The method of claim 4, wherein the forming the hard mask comprises a plurality of cycles, and each of the plurality of cycles comprises:
depositing a silicon layer; and
performing a nitridation process on the silicon layer.

6. The method of claim 5, wherein the depositing the silicon layer is performed with a bias power applied, and the hard mask has a sidewall thickness and a bottom thickness greater than the sidewall thickness.

7. The method of claim 1 further comprising, before the hard mask is formed, depositing a dielectric layer on the protruding fin.

8. The method of claim 7, wherein the dielectric layer comprises a same dielectric material as the shallow trench isolation region.

9. The method of claim 1, wherein when the disposable interposer is etched, the shallow trench isolation region is separated from the etching chemical by a bottom portion of the hard mask.

10. The method of claim 9, wherein the gate stack contacts the bottom portion of the hard mask.

11. A method comprising:
forming a shallow trench isolation region in a semiconductor substrate, wherein a part of the semiconductor substrate aside of the semiconductor substrate forms a semiconductor protrusion;
forming a first semiconductor nanostructure overlapping, and spaced apart from, the semiconductor protrusion;
forming a hard mask over the shallow trench isolation region; and
forming a gate stack comprising:
a first portion between the first semiconductor nanostructure and the semiconductor protrusion; and
a second portion, wherein the hard mask is between the shallow trench isolation region and the second portion of the gate stack.

12. The method of claim 11, wherein the hard mask comprises a different dielectric material than the shallow trench isolation region.

13. The method of claim 12, wherein the forming the hard mask comprises a deposition process, and an etching process following the deposition process.

14. The method of claim 11 further comprising forming a dielectric liner between, and in contact with, the hard mask and the semiconductor protrusion.

15. The method of claim 11 further comprising forming a second semiconductor nanostructure overlapping, and spaced apart from, the first semiconductor nanostructure, wherein the gate stack further comprises a third portion between the first semiconductor nanostructure and the second semiconductor nanostructure.

16. The method of claim 11, wherein a topmost end of the hard mask is lower than a top of the semiconductor protrusion.

17. A method comprising:
forming a shallow trench isolation region in a semiconductor substrate, wherein a portion of the semiconductor substrate is aside of and contacting the shallow trench isolation region to act as a semiconductor strip;
forming a dielectric liner over and contacting the shallow trench isolation region;
forming a dielectric hard mask over the dielectric liner, wherein a sidewall portion of the dielectric liner comprises opposing sidewalls contacting the dielectric hard mask and the semiconductor strip; and
forming a gate stack over and contacting the dielectric hard mask.

18. The method of claim 17, wherein the dielectric hard mask is formed of a different material than the shallow trench isolation region.

19. The method of claim 17, wherein at a time the gate stack is formed, the dielectric hard mask comprises a curved top surface, with a middle portion of the curved top surface being lower than portions of the curved top surface on opposite sides of the middle portion.

20. The method of claim 17, wherein the forming the dielectric hard mask comprising a deposition process and an etching process following the deposition process.
